(19) United States
(12) Patent Application Publication
(10) Pub. No.: US 2024/0250016 A1
(43) Pub. Date: Jul. 25, 2024

(54) Dielectric Material Layer, Surface Treatment Method, Package Substrate, and Electronic Device

(71) Applicant: Honor Device Co., Ltd., Shenzhen (CN)

(72) Inventors: Xueping Guo, Shenzhen (CN); Zihao Liu, Shenzhen (CN)

(21) Appl. No.: 18/005,745

(22) PCT Filed: Aug. 24, 2022
(86) PCT No.: PCT/CN2022/114556

§ 371 Date: Jan. 17, 2023

(30) Foreign Application Priority Data
Sep. 8, 2021 (CN) 202111050638.2

(51) Int. Cl. H01L 23/498; C25D 5/48; C25D 7/12; H01L 21/48; H01L 23/00

(52) U.S. Cl. CPC H01L 23/49894; C25D 5/48; C25D 7/123; H01L 21/4857; H01L 23/49822; H01L 24/16; H01L 2224/16227

(57) ABSTRACT

Disclosed in this application are a surface treatment method, a package substrate, and an electronic device. The package substrate comprises a dielectric material layer. The dielectric material layer includes resin and spherical SiO₂ filled in the resin. An outer surface of at least part of the spherical SiO₂ is covered with a sacrificial layer. The sacrificial layer covering the outer surface of the spherical SiO₂ is treated, to reduce the volume of the sacrificial layer covering the outer surface of the spherical SiO₂, so that a cavity is formed around the spherical SiO₂ or part of the spherical SiO₂ is disengaged from the dielectric material layer. In this way, a metal layer may enter the cavity around the spherical SiO₂ and form a new anchor point between the spherical SiO₂ and surrounding resin.

### CROSS-REFERENCE TO RELATED APPLICATIONS

This application is a national stage of International Application No. PCT/CN2022/114556, filed on Aug. 24, 2022, which claims priority to Chinese Patent Application No. 202111050638.2, filed on Sep. 8, 2021. The disclosures of both of the aforementioned applications are hereby incorporated by reference in their entireties.

### TECHNICAL FIELD

This application relates to the field of material technologies, and in particular, to a dielectric material layer, a surface treatment method, a package substrate, and an electronic device.

### BACKGROUND

A package substrate is a structure that can provide a chip with electrical connection, protection, support, heat dissipation, assembly, and other functions, to achieve the objectives of implementing multiple pins, reducing the volume of a packaged product, improving electrical performance and heat dissipation, and implementing ultra-high density or multi-chip modularization.

In an embodiment, a package substrate includes a plurality of dielectric material layers, a core board arranged between two adjacent dielectric material layers, and a wiring layer bonded to a surface of each dielectric material layer. At present, the dielectric material layers are generally formed of an ABF (Ajinomoto Build-up Film) material. The ABF material includes resin and spherical SiO₂ filled in the resin. To enhance the bonding force between a wiring layer and an ABF dielectric material layer, before the wiring layer is formed, a Desmear process treatment needs to be performed on a surface of the ABF dielectric material layer, that is, a bulking and etching treatment needs to be performed on the resin on the surface of the ABF dielectric material layer, to form an appropriate roughness on the surface of the ABF dielectric material layer, so that the wiring layer can form firm physical riveting to the rough surface of the ABF dielectric material layer.

However, to meet requirements in directions of a low CTE (coefficient of thermal expansion, coefficient of thermal expansion), a low dielectric constant, and a low loss of the ABF dielectric material layer, the content of the spherical SiO₂ filled in the ABF material is usually relatively high. When the content of the spherical SiO₂ filled in the ABF dielectric material layer is relatively high, after the bulking and etching treatment is performed on the resin on the surface of the ABF dielectric material layer, a surface with a roughness satisfying the requirements may fail to be obtained. As a result, the bonding force between a wiring layer subsequently formed through deposition and the surface of the ABF dielectric material layer cannot meet the requirements.

### SUMMARY

To resolve the technical problem that when the content of spherical SiO₂ filled in an ABF dielectric material layer is relatively high, after a bulking and etching treatment is performed on resin on a surface of the ABF dielectric material layer, a surface with a roughness satisfying a requirement may fail to be obtained, this application provides a dielectric material layer, a surface treatment method, a package substrate, and an electronic device.

In a first aspect, this application provides a dielectric material layer, applicable to a package substrate, where the dielectric material layer is arranged between a component layer and a main board, and the dielectric material layer includes resin and spherical SiO₂ filled in the resin; an outer surface of at least part of the spherical SiO₂ is covered with a sacrificial layer; and the sacrificial layer can be eroded by a first solution that does not react with the spherical SiO₂, and the first solution has a stronger capability of eroding the sacrificial layer than a capability of eroding the resin, where the first solution is a solution used in an oxidative degumming stage in a surface treatment of the dielectric material layer, or, the first solution is a solution used in a neutralization stage in the surface treatment of the dielectric material layer; and during the surface treatment of the dielectric material layer, the sacrificial layer is used for being eroded by the solution used in the oxidative degumming stage, or, the sacrificial layer is used for being eroded by the solution used in the neutralization stage.

In an embodiment, the sacrificial layer is formed of inorganic matter that can be eroded by an acid solution, and products produced by the sacrificial layer reacting with the acid solution include at least one of a salt soluble in water, a gas, or water.

In an embodiment, the sacrificial layer includes at least one material of Na₂CO₃, K₂CO₃, NaHCO₃, or KHCO₃.

In an embodiment, the sacrificial layer adopts organic matter capable of being hydrolyzed in an acid solution.

In an embodiment, the organic matter is protein, lipid, or polysaccharide.

In an embodiment, the acid solution is hydrochloric acid, sulfuric acid, or nitric acid.

In an embodiment, the sacrificial layer is formed of organic matter modified epoxy resin or modified cyanate capable of being eroded by an alkaline oxidant, where the modified epoxy resin is epoxy resin in which at least one ether bond and/or one hydroxyl is added to a skeleton and/or a side chain; and the modified cyanate is cyanate in which at least one ether bond and/or one hydroxyl is added to a skeleton and/or a side chain.

In an embodiment, the alkaline oxidant is an alkaline potassium permanganate solution.

In an embodiment, a thickness of the sacrificial layer ranges from 0.5 μm to 1 μm.

In an embodiment, a mass percent of the spherical SiO₂ filled in the resin in the dielectric material layer accounts is greater than or equal to 60%, the spherical SiO₂ of different particle diameters is filled in the resin, and the particle diameters of the spherical SiO₂ range from 1 μm to 5 μm.

In a second aspect, this application further provides a surface treatment method for a dielectric material layer, where the dielectric material layer is any dielectric material layer in the first aspect, and the method includes:
performing a swelling and bulking treatment on a target surface of the dielectric material layer, where the target surface is a surface bonded to a wiring layer;
performing an oxidation treatment on the target surface of the dielectric material layer, removing resin on the target surface, and exposing spherical SiO₂ covered with a sacrificial layer from the target surface; and
eroding the sacrificial layer on an outer surface of the spherical SiO₂ exposed from the target surface by using a first solution, and forming a cavity around the spherical SiO₂ or disengaging part of the spherical SiO₂ from the dielectric material.

In an embodiment, the method further includes: depositing a first metal layer of a first thickness on the target surface;

performing an electroplating treatment on the first metal layer, to form a second metal layer of a second thickness, where the second metal layer has the same pattern as a target wiring layer, and the second thickness is greater than the first thickness; and

removing metal deposited on a first region of the first metal layer, to form the target wiring layer on the target surface, where the first region is a region that is not covered by the second metal layer in the first metal layer.

In a third aspect, this application further provides a package substrate, including at least one dielectric material layer in the first aspect, and/or,
a core board,
where a wiring layer is prepared on a target surface of the dielectric material layer.

In a third aspect, this application further provides an electronic device, the electronic device including the package substrate according to the third aspect, a component layer, and a main board, the package substrate being arranged between the component layer and the main board, where the component layer includes a passive element and/or a chip.

In an embodiment, the package substrate includes a first dielectric material layer, where a first blind via is provided in the first dielectric material layer;
a wiring layer is prepared on each of a first surface and a second surface opposite to each other of the first dielectric material layer; and
the passive element and/or a first part of pins in the chip are connected to the wiring layer on the first surface, and the passive element and/or a second part of pins in the chip are connected to the wiring layer of the second surface through the first blind via.

In an embodiment, the package substrate further includes a second dielectric material layer and a core board, where the core board is arranged between the first dielectric material layer and the second dielectric material layer;
a second blind via is provided in the core board, and a third blind via is provided in the second dielectric material layer;
a wiring layer is prepared on each of a third surface and a fourth surface opposite to each other of the second dielectric material layer;
the passive element and/or a third part of pins in the chip are connected to the wiring layer on the third surface through the first blind via and the second blind via, and the passive element and/or a fourth part of pins in the chip are connected to the wiring layer on the fourth surface through the first blind via, the second blind via, and the third blind via; and
the wiring layer on the fourth surface is connected to the main board.

In an embodiment, the passive element and/or the first part of pins in the chip are connected to the wiring layer on the first surface by a first solder ball, and the wiring layer on the fourth surface is connected to the main board by a second solder ball.

In summary, this application provides a dielectric material layer, a surface treatment method, a package substrate, and an electronic device. An outer surface of spherical SiO₂ is covered with a sacrificial layer. In this way, after resin on a surface of the dielectric material layer is removed, the spherical SiO₂ covered with the sacrificial layer is exposed, so that the sacrificial layer covering the outer surface of the spherical SiO₂ can be treated to reduce the volume of the sacrificial layer covering the outer surface of the spherical SiO₂, thereby forming a cavity around the spherical SiO₂ or disengaging part of the spherical SiO₂ from the dielectric material layer. In this way, when the metal layer is deposited on the surface of the dielectric material layer after a surface treatment, the metal layer enters the cavity around the spherical SiO₂, and a new anchor point is formed between the spherical SiO₂ and surrounding resin. The metal layer can grasp the spherical SiO₂ tightly like a “claw” to improve the bonding force between the metal layer and the surface of the dielectric material layer, thereby improving the bonding force between a wiring layer made on the metal layer and the surface of the dielectric material layer.

### BRIEF DESCRIPTION OF THE DRAWINGS

To describe the technical solutions in the embodiments of the present invention or in the prior art more clearly, the following briefly introduces the accompanying drawings required for descriptions in the embodiments or the prior art. Apparently, the accompanying drawings in the following descriptions show some embodiments of the present invention, and a person of ordinary skill in the art may still derive other drawings from these accompanying drawings without creative efforts.

FIG. 1A is a schematic structural diagram of an electronic device;

FIG. 1B is a schematic structural diagram of an ABF dielectric material in the prior art;

FIG. 1C is a schematic structural diagram of another ABF dielectric material in the prior art;

FIG. 1D is a schematic flowchart of a method for performing a Desmear process treatment and a SAP process treatment on a surface for a dielectric material layer;

FIG. 2A is a schematic structural diagram of a dielectric material layer according to an embodiment of this application;

FIG. 2B is a schematic structural diagram of spherical SiO₂ covered with a sacrificial layer according to an embodiment of this application;

FIG. 2C is a schematic structural diagram of a dielectric material layer after a surface treatment according to an embodiment of this application;

FIG. 2D is a schematic structural diagram of a dielectric material layer and a wiring layer being bonded according to an embodiment of this application;

FIG. 3A is a flowchart of a surface treatment method according to an embodiment of this application;

FIG. 3B is a schematic structural diagram of a dielectric material layer and a first metal layer being bonded according to an embodiment of this application;

FIG. 3C is a flowchart of another surface treatment method according to an embodiment of this application;

FIG. 3D is a flowchart of still another surface treatment method according to an embodiment of this application; and

FIG. 4A is a schematic structural diagram of a chip and a passive element being packaged by a package substrate provided in an embodiment of this application according to an embodiment of this application.

### DESCRIPTIONS OF REFERENCE NUMERALS

1—display screen, 2—battery, 3—rear housing, 4—middle frame, 5—secondary board, 6—main board, 7—chip, and 8—package substrate;
10—first dielectric material layer, 20—second dielectric material layer, 30—core board, 40—wiring layer, 50—chip, 60—passive element, 70—main board, 80—first solder ball, 90—second solder ball, 110—first blind via, 120—first surface, 130—second surface, 210—third blind via, 220—third surface, 230—fourth surface, and 310—second blind via.

### DETAILED DESCRIPTION OF ILLUSTRATIVE EMBODIMENTS

The following clearly and completely describes the technical solutions in embodiments of this application with reference to the accompanying drawings in the embodiments of this application. Apparently, the described embodiments are merely some but not all of the embodiments of this application. All other embodiments obtained by a person of ordinary skill in the art based on the embodiments of this application without creative efforts fall within the protection scope of this application.

Before the technical solutions in this application are described, a technical scenario in this application is first described.

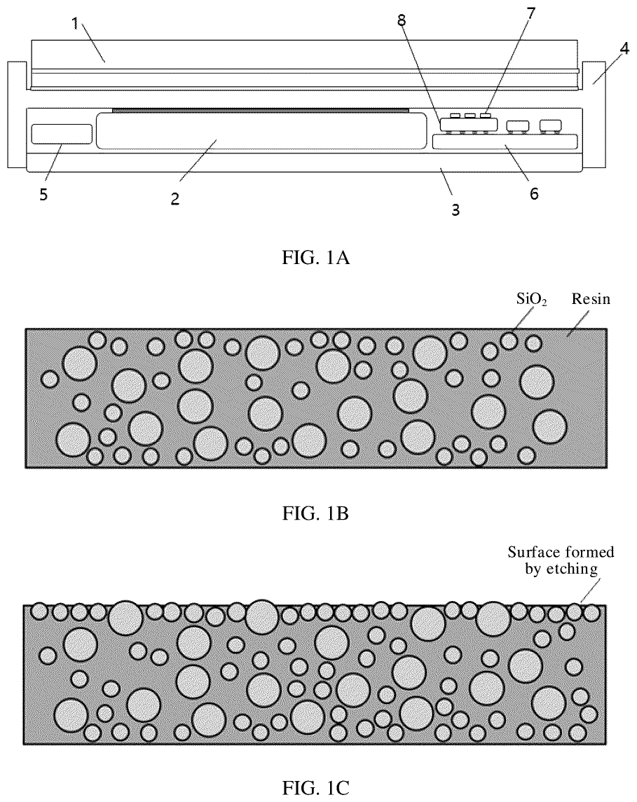

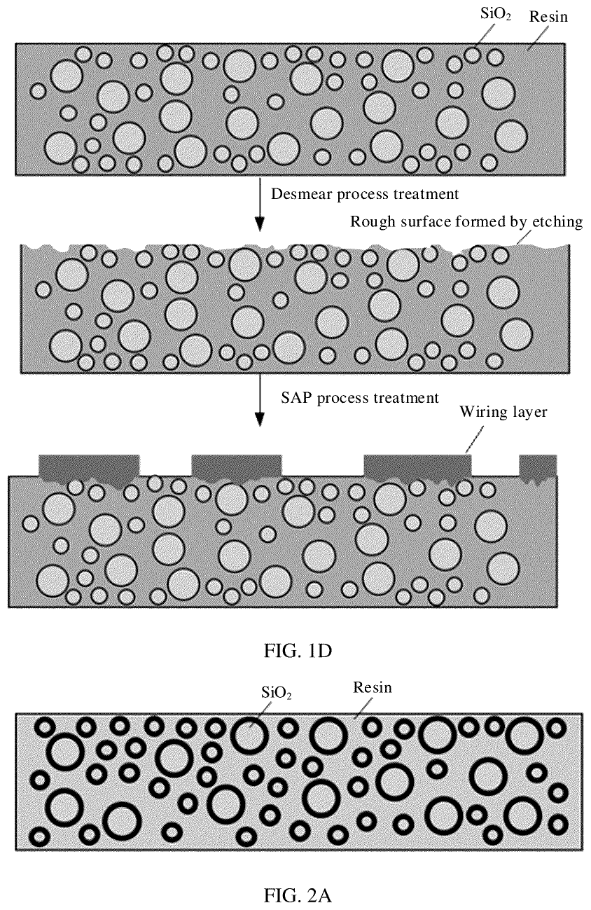

FIG. 1A is a schematic structural diagram of an electronic device. The electronic device includes a display screen 1, a battery 2, a rear housing 3, a middle frame 4, a secondary board 5, a main board 6, a chip 7, and a package substrate 8. The package substrate 8 is arranged between the main board 6 and the chip 7. The chip 7 is packaged by the package substrate 8 and connected to the main board 6. The package substrate 8 can provide the chip 7 with functions such as electrical connection, protection, support, heat dissipation, and assembly. In this way, interconnection between chips and/or between a chip and a main board in the electronic device can be implemented by the package substrate. In an embodiment, in the package substrate, a core board having interwoven glass fiber inside is used as a dielectric material layer.

As packages of chips such as CPUs, ASICs, GPUs, and FPGAs require increasingly high interconnection density and functionality of the package substrate, tremendous pressure is brought to conventional package substrates. A package substrate needs to keep increasing the wiring density and increasing a quantity of dielectric material layers to satisfy interconnection requirements of the chips. However, because a conventional core board has interwoven glass fiber inside, it is difficult to form a blind via of a relatively small size by laser drilling, making it impossible to meet a requirement of fine wiring on the core board.

Based on this, an ABF material has emerged. As shown in FIG. 1B, the ABF material is formed by resin and spherical SiO₂ filled in the resin. Therefore, when the ABF material is used as a dielectric material layer in the package substrate, a blind via of a relatively small size can be formed in an ABF dielectric material layer by laser drilling to meet the requirement of fine wiring.

When the package substrate is applied to the electronic device, a wiring layer needs to be prepared on the surface of the ABF dielectric material layer of the package substrate, to implement connection between chips and and/or between a chip and a main board. In an embodiment, to improve the bonding strength between a wiring layer and the ABF dielectric material layer, a Desmear process treatment is performed on the surface of the ABF dielectric material layer, that is, a bulking and etching treatment is performed on the resin on the surface of the ABF dielectric material layer, thereby forming an appropriate roughness on the surface of the ABF dielectric material layer. Next, the wiring layer is prepared on the surface of the treated ABF dielectric material layer, so that the wiring layer can form a firm physical riveting with the rough surface of the ABF dielectric material layer.

However, to meet requirements in directions of a low CTE, a low dielectric constant, and a low loss of the ABF dielectric material layer, the content of the spherical SiO₂ filled in the ABF dielectric material layer is usually relatively high. When the content of the spherical SiO₂ filled in the ABF dielectric material layer is relatively high, after is the bulking and etching treatment is performed on the resin on the surface of the ABF dielectric material layer, as shown in FIG. 1C, the surface of the ABF dielectric material layer is occupied by the spherical SiO₂, making it impossible to continue to erode the resin. At this time, a surface with a roughness satisfying the requirements has not been obtained. As a result, the bonding force between a wiring layer subsequently formed through preparation and the surface of the ABF dielectric material layer cannot meet the requirements.

To resolve the above technical problems, in an embodiment, the spherical SiO₂ exposed from the surface may be eroded by using a hydrofluoric acid solution to form an appropriate roughness on the surface of the ABF dielectric material layer. However, the hydrofluoric acid solution is harmful to the environment and human body, and is not readily applicable to actual production.

To resolve the technical problem that the bonding force between a wiring layer and a surface of an ABF dielectric material layer in the prior art cannot meet requirements, this application provides an improved dielectric material layer.

For ease of understanding the technical solutions provided in this application, the following describes a Desmear process and a SAP process (Semi-Additive Process, semi-additive process).

The Desmear process is also referred to as a process for treating a hole interior or a surface. In a process of treating a surface, in the Desmear process, the bulking and etching treatment is mainly performed on a pressed and precured surface of the dielectric material layer to form an appropriate roughness, so that a wiring layer can form firm physical riveting to the rough surface of the dielectric material layer.

A process of a Desmear process treatment mainly includes three stages: a swelling and bulking stage, an oxidative degumming stage, and a neutralization stage.

Treatment reagents used in the swelling and bulking stage are mainly polyols. Polyols enter a surface and an interior of resin in the dielectric material layer and react with hydrophilic group hydroxyls (—OH) of the surface or the interior of the resin to form hydrogen bonds, to produce a bulked effect on the surface and the interior of the resin, so that an alkaline potassium permanganate solution in the next stage can enter the interior of the resin.

A treatment reagent used in the oxidative degumming stage is mainly an alkaline potassium permanganate solution, which has a strong oxidation capability. The alkaline potassium permanganate solution attacks ether bonds inside the resin and oxidizes the ether bonds into soluble aromatic alcohol, ketone, and the like, so that a cavity is formed inside the resin, that is, a rough surface is formed on the surface of the dielectric material layer.

A treatment reagent used in the neutralization stage is mainly sulfuric acid. The sulfuric acid is mainly used for neutralizing the alkaline potassium permanganate solution in the oxidative degumming stage.

The SAP process is shown in FIG. 1D. A dielectric material layer having a surface with a roughness satisfying requirements is obtained after the Desmear process treatment is performed, and the process enters a SAP process stage. The SAP process includes: depositing a relatively thin metal layer on the surface of the dielectric material layer, and then manufacturing a required wiring layer on the metal layer.

The improved dielectric material layer provided in this application is described below with reference to the accompanying drawings.

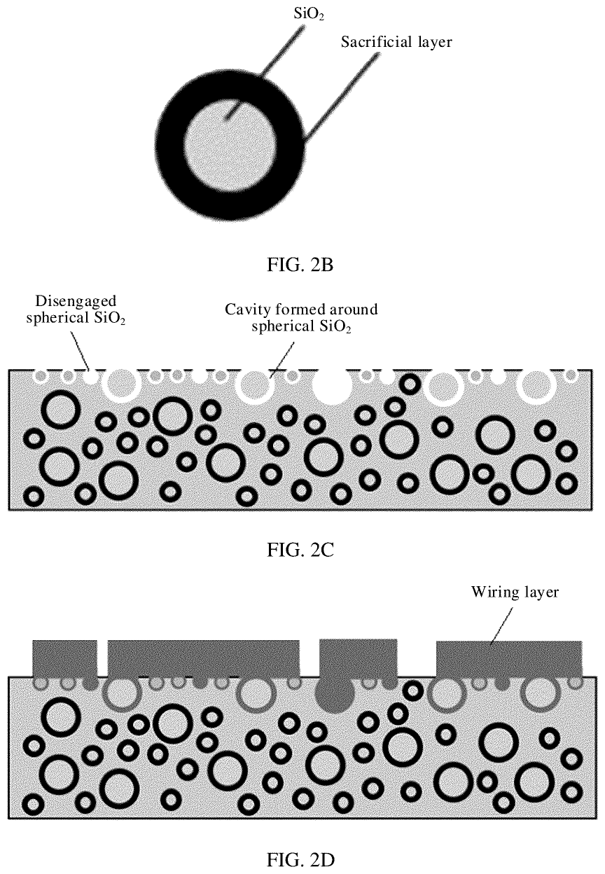

As shown in FIG. 2A and FIG. 2B, a dielectric material layer provided in an embodiment of this application includes resin and spherical SiO₂ filled in the resin; and an outer surface of at least part of the spherical SiO₂ is covered with a sacrificial layer.

In the improved dielectric material layer of this application, the outer surface of the spherical SiO₂ is covered with the sacrificial layer. In this way, as shown in FIG. 2C, after resin on a surface of the dielectric material layer is removed, the spherical SiO₂ covered with the sacrificial layer is exposed, so that the sacrificial layer covering the outer surface of the spherical SiO₂ can be treated to reduce the volume of the sacrificial layer covering the outer surface of the spherical SiO₂, thereby forming a cavity around the spherical SiO₂ or disengaging part of the spherical SiO₂ from the dielectric material layer. In this way, as shown in FIG. 2D, when the metal layer is deposited on the surface of the dielectric material layer after a surface treatment, the metal layer enters the cavity around the spherical SiO₂, and a new anchor point is formed between the spherical SiO₂ and surrounding resin. The metal layer can grasp the spherical SiO₂ tightly like a “claw” to improve the bonding force between the metal layer and the surface of the dielectric material layer, thereby improving the bonding force between a wiring layer made on the metal layer and the surface of the dielectric material layer.

It can be learned that, compared with the solution of directly eroding the spherical SiO₂ by using the hydrofluoric acid solution, for the dielectric material layer provided in this application, instead of the solution of directly eroding the spherical SiO₂, the sacrificial layer covering the spherical SiO₂ is eroded, thereby avoiding the hydrofluoric acid solution that is harmful to both the environment and human body.

The sacrificial layer in this application is further described below.

The sacrificial layer is a structure covering the outer surface of the spherical SiO₂. The material of the sacrificial layer is not limited in this application, as long as the sacrificial layer can be eroded by a solution to reduce the volume, the solution has a stronger capability of eroding the sacrificial layer than eroding resin, and the solution does not react with the spherical SiO₂.

In a first embodiment, the sacrificial layer may be formed of organic matter or inorganic matter that can be eroded by an acid solution that does not react with the spherical SiO₂.

The acid solution does not react with the spherical SiO₂, that is, the acid solution is not a hydrofluoric acid solution. Therefore, compared with the solution of directly etching the spherical SiO₂, this application can avoid using the hydrofluoric acid solution that is harmful to the environment and human body.

In the first embodiment, in a case that the sacrificial layer is formed of inorganic matter, it is required that the inorganic matter can react with one acid solution, and the volume of the inorganic matter can be reduced after reaction, thereby forming a cavity around the spherical SiO₂. For example, after the inorganic matter reacts with the acid solution, at least one of a salt soluble in water, water, or a gas is produced. In another example, after the inorganic matter reacts with the acid solution, the volume of a new produced inorganic matter is less than the volume of the sacrificial layer before the reaction. In this way, a cavity can be formed around the spherical SiO₂.

In a specific example, the inorganic matter may be Na₂CO₃, K₂CO₃, NaHCO₃, or KHCO₃, so that the inorganic matter can be dissolved in a commonly used acid solution such as hydrochloric acid, sulfuric acid, or nitric acid.

For example, the sacrificial layer is formed of inorganic matter Na₂CO₃ and the acid solution is hydrochloric acid. Na₂CO₃ reacts with hydrochloric acid to produce sodium chloride, water, and carbon dioxide gas. Sodium chloride is a salt soluble in water. In this way, after the sacrificial layer formed of Na₂CO₃ reacts with the hydrochloric acid, a cavity is formed around the spherical SiO₂ or part of the spherical SiO₂ is disengaged from the dielectric material layer.

It should be noted that, the material forming the sacrificial layer may be one of Na₂CO₃, K₂CO₃, NaHCO₃, or KHCO₃, or may be two, three, or four of Na₂CO₃, K₂CO₃, NaHCO₃, or KHCO₃, which is not limited by this application. For example, the material forming the sacrificial layer may include two inorganic materials, Na₂CO₃ and K₂CO₃, and both the two inorganic materials can be dissolved in the acid solution.

It should be further noted that, compared with the inorganic matters NaHCO₃ and KHCO₃, the inorganic matters Na₂CO₃ and K₂CO₃ have more stable material performance. Therefore, the structure of the sacrificial layer formed of the inorganic matters Na₂CO₃ and K₂CO₃ is more stable.

In the first embodiment, in a case that the sacrificial layer is formed of organic matter that can be dissolved in the acid solution, it is also required that the organic matter can react with one acid solution and has a reduced volume after reaction, thereby forming a cavity around the spherical SiO₂. For example, the organic matter may be protein, lipid, or polysaccharide. The organic matter protein, lipid, or polysaccharide is easily hydrolyzed in an acid solution.

A method for preparing the sacrificial layer is not limited in this application. For example, the sacrificial layer may be formed by using a preparation method such as a hydrothermal reaction chemical synthesis method or a spraying method. For example, the sacrificial layer is formed by using the hydrothermal reaction chemical synthesis method. Prepared spherical SiO₂ and raw materials used for producing the inorganic matter Na₂CO₃ may be added to a reaction kettle. The sacrificial layer of inorganic matter Na₂CO₃ covering the outer surface of the spherical SiO₂ is formed by applying a certain temperature and pressure.

In a second embodiment, the sacrificial layer may be formed of organic matter that can be oxidized by a basic oxide. The basic oxide has higher strength of oxidizing the sacrificial layer of organic matter than that of oxidizing the resin in the dielectric material.

In this way, in the process of the surface treatment of the dielectric material layer, after the spherical SiO₂ is exposed, the surface of the dielectric material layer is filled by the spherical SiO₂. In a case that the resin cannot continue to be eroded, the basic oxide may be used to erode the sacrificial layer covering the outer surface of the spherical SiO₂, so that the cavity is formed on the outer surface of the spherical SiO₂ or part of the spherical SiO₂ is disengaged from the dielectric material.

In a specific example, the organic matter that can be oxidized by an alkaline oxidant may be organic matter modified epoxy resin or modified cyanate. The modified epoxy resin is epoxy resin in which at least one ether bond and/or one hydroxyl is added to a skeleton and/or a side chain. the organic matter modified cyanate is organic matter cyanate in which at least one ether bond and/or one hydroxyl is added to a skeleton and/or a side chain.

It can be learned from the above description of the Desmear process treatment that, in the oxidative degumming stage, the alkaline potassium permanganate solution can attack ether bonds inside the resin to form a cavity inside the resin, thereby forming a rough surface on the surface of the dielectric material layer. Therefore, in this application, more ether bonds are added to the skeleton and/or the side chain of the organic matter epoxy resin or cyanate, so that the alkaline oxidant can quickly attack the organic matter epoxy resin or cyanate in the sacrificial layer.

It can be further learned from the above description of the Desmear process treatment that, in a swelling and bulking stage, polyols react with hydrophilic groups hydroxyls in the resin to expand the channel and form a swollen and bulked effect. Therefore, in this application, more hydroxyls are added to the skeleton and/or the side chain of the organic matter epoxy resin or cyanate, so that in the swelling and bulking stage, the modified epoxy resin or the organic matter modified cyanate can attract more polyols to react with the hydroxyl compared with unmodified resin, forming a better swollen effect to the sacrificial layer. In subsequent steps, a large amount of the alkaline oxidant may enter the interior of the organic matter modified epoxy resin or modified cyanate for oxidation, making it easier to remove the modified epoxy resin or the organic matter modified cyanate by using the alkaline oxidant.

It should be noted that, in this application, that a solution has a higher capability of eroding the sacrificial layer than that of eroding the resin means that the solution can erode the sacrificial layer only but cannot erode the resin. For example, the acid solution in the first embodiment only erodes the inorganic matter Na₂CO₃, but does not erode the resin. Alternatively, in a case that both the resin and the sacrificial layer are in contact with a solution, in the foregoing second embodiment, the solution can erode more of the sacrificial layer. For example, in a case that both the resin and the modified epoxy resin are in contact with the basic oxide, the basic oxide can oxidize more of the modified epoxy resin.

The alkaline oxidant is not limited in this application, as long as the sacrificial layer can be oxidized and removed and the strength of oxidizing the sacrificial layer of the alkaline oxidant is greater than the strength of oxidizing the resin in the dielectric material layer. For example, the alkaline oxidant may adopt an alkaline potassium permanganate solution or an alkaline sodium permanganate solution. In a case that the alkaline oxidant adopts the alkaline potassium permanganate solution, during the treatment of the surface of the dielectric material layer, an alkaline potassium permanganate solution in an existing process system can be used directly without adding a new process and a new treatment reagent.

It should be noted that, the resin in the dielectric material layer is not limited in this application, and may be, for example, epoxy resin or modified cyanate.

It should be further noted that, the methods for obtaining the organic matter modified epoxy resin and modified cyanate are not limited in this application. Any feasible method in the prior art can be used to prepare the organic matter modified epoxy resin or modified cyanate.

It should be further noted that, the outer surface of all the spherical SiO₂ filled in the resin may be covered with the sacrificial layer, or, the outer surface of part of the spherical SiO₂ filled in the resin is covered with the sacrificial layer, which is not limited in this application, as long as it can be ensured that when the dielectric material layer of this application is used, after the resin on the surface of the dielectric material layer is removed, the outer surface of part of spherical SiO₂ is covered with the sacrificial layer.

It should be further noted that, the sacrificial layer in the embodiments of this application may cover the outer surface of the spherical SiO₂ evenly or cover the outer surface of the spherical SiO₂ unevenly, which is not limited in this application.

In addition, the thickness of the sacrificial layer is also not limited in this application. For example, the thickness of the sacrificial layer may range from 0.5 μm to 1 μm. It is easier to implement the sacrificial layer with a thickness ranging from 0.5 μm to 1 μm in a production process.

In summary, in this application, the outer surface of the spherical SiO₂ is covered with the sacrificial layer, so that a cavity can be formed on the outer surface of the spherical SiO₂ or part of the spherical SiO₂ can be disengaged from the dielectric material layer by eroding the sacrificial layer, to obtain a surface with a roughness satisfying requirements. Therefore, the solutions provided in this application resolve the problem that, because the content of the spherical SiO₂ filled inside the dielectric material layer becomes increasingly high, it becomes impossible to continue with etching to obtain a surface with a roughness satisfying the requirements, and can avoid using a hydrofluoric acid that is harmful to the environment and human body, thereby keeping the spherical SiO₂.

Further, for the dielectric material layer provided in this application, a mass percent of the spherical SiO₂ filled in the resin in the dielectric material layer greater than or equal to 60%. The spherical SiO₂ filled in the resin includes spherical SiO₂ of different particle diameters. The particle diameters of the spherical SiO₂ filled in the resin may range from 1 μm to 5 μm.

A better filling ratio can be implemented by filling the spherical SiO₂, with different particle diameters in the resin. A filling amount of a mass percent greater than or equal to 60% can meet the development trend in directions of a lower CTE, a lower dielectric constant, and a lower loss, and better mechanical strength can be implemented.

It should be noted that, in the above embodiments, that the sacrificial layer may be formed of organic matter or inorganic matter that can be dissolved in an acid solution, or, that the sacrificial layer may be formed of organic matter that can be oxidized by an alkaline oxidant is only used for exemplary description, but represents no limitation of the material and quantity of the sacrificial layers in this application. For example, the sacrificial layer may further include some organic matter or inorganic matter that cannot be dissolved in an acid solution, or, the sacrificial layer may include some organic matter that cannot be oxidized by an alkaline oxidant. In another example, the sacrificial layer may be formed of both organic matter or inorganic matter that can be dissolved in an acid solution and organic matter that can be oxidized by an alkaline oxidant. In this case, the sacrificial layer may be a multi-layer structure formed by stacking. One or more layers of the multi-layer structure may be formed of organic matter or inorganic matter that can be dissolved in an acid solution, and one or more layers of the multi-layer structure may be formed of organic matter that can be oxidized by an alkaline oxidant.

This application further provides a surface treatment method for the above improved dielectric material layer of this application. The surface treatment method is described below.

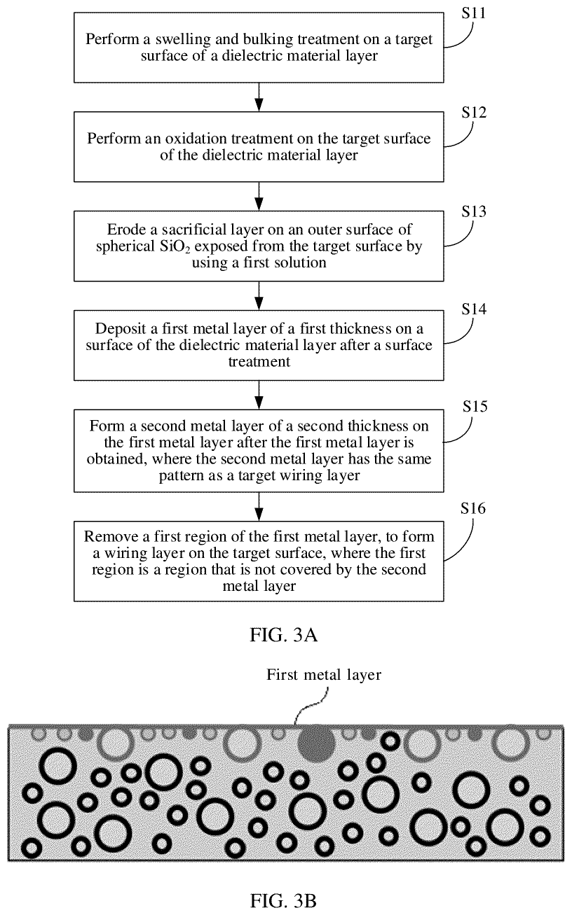

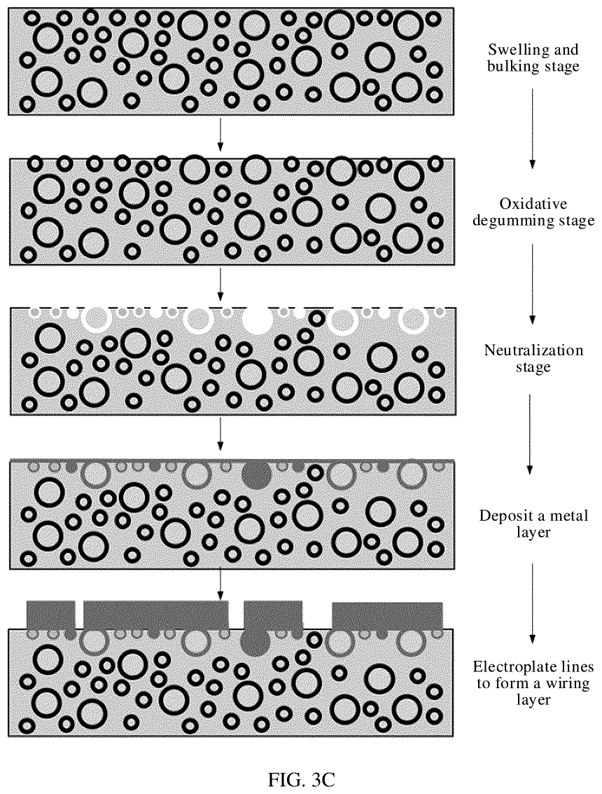

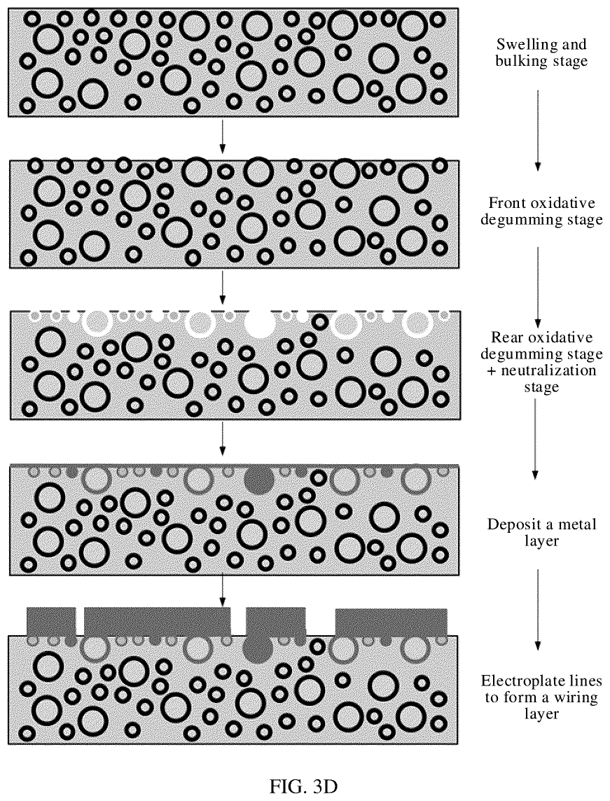

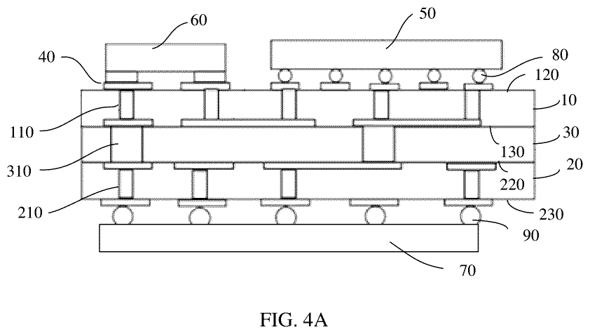

As shown in FIG. 3A, the surface treatment method for the above improved dielectric material provided in this application includes the following steps:

Step S11. Perform a swelling and bulking treatment on a target surface of a dielectric material layer, where the target surface is a surface bonded to a wiring layer.

Through swelling and bulking of the resin in the dielectric material, this step reduces the bonding force between polymers, to facilitate an etching treatment of the resin in step S12. Specifically, polyols may be used as treatment reagents in the swelling and bulking treatment. Polyols enter a surface and an interior of the resin of the dielectric material and react with hydrophilic group hydroxyls (—OH) of the surface or the interior of the resin to form hydrogen bonds and swell the resin, making it convenient for the treatment reagent (for example, an alkaline potassium permanganate solution) used in step S12 to enter the interior of the resin.

Step S12. Perform an oxidation treatment on the target surface of the dielectric material layer, remove resin on the target surface, and expose spherical SiO₂ covered with a sacrificial layer from the target surface.

To meet requirements in directions of a lower CTE, a lower dielectric constant, and a lower loss of the dielectric material layer, the proportion of the spherical SiO₂ filled in the dielectric material layer keeps increasing, resulting in an increasingly small thickness of the resin on the surface of the dielectric material layer. Therefore, the very thin resin on the surface of the dielectric material layer exposes the spherical SiO₂ covered with the sacrificial layer after an oxidation and etching treatment in step S12. However, the roughness of the surface of the dielectric material layer cannot meet the requirements at this time, and it is necessary to combine step S13 to further treat the surface of the dielectric material layer after the initial treatment combined.

In step S12, the oxidation treatment may be performed on the target surface of the dielectric material layer by using an alkaline potassium permanganate solution.

It should be noted that, the target surface of the dielectric material may be one surface or two opposite surfaces of the dielectric material layer, which is not limited in this application. For example, a wiring layer is bonded to each of an upper surface and a lower surface of the dielectric material layer. In this application scenario, the target surface of the dielectric material may include an upper surface and a lower surface.

It should be further noted that, after the oxidation and etching treatment in step S12, in the exposed spherical SiO₂, an outer surface of part of the spherical SiO₂ may be covered with the sacrificial layer, or an outer surface of all the spherical SiO₂ may be covered with the sacrificial layer, which is not limited in this application.

Step S13. Erode the sacrificial layer on the outer surface of the spherical SiO₂ exposed from the target surface by using a first solution, thereby reducing the volume of the sacrificial layer.

In step S13, the first solution used to erode the sacrificial layer is determined based on the material used for the sacrificial layer. For a selectable material of the sacrificial layer and the corresponding first solution, reference may be made to the description of the sacrificial layer in the above embodiments of the dielectric material, and details are not described herein again.

After the treatments in step S11 to step S13, the volume of the sacrificial layer on the outer surface of the spherical SiO₂ exposed from the target surface of the dielectric material layer is reduced, so that a cavity is formed on the outer surface of the spherical SiO₂ or part of the spherical SiO₂ is disengaged from the dielectric material.

After step S13 is completed, the SAP process treatment may be continued. That is, a relatively thin metal layer is deposited on the surface of the dielectric material layer, and then a required wiring layer is manufactured on the metal layer, which may specifically include following steps:

Step S14. Deposit a first metal layer of a first thickness on the surface of the dielectric material layer after a surface treatment.

As shown in FIG. 3B, after the first metal layer is deposited on the surface of the dielectric material layer after a surface treatment, the first metal layer enters the cavity around the spherical SiO₂, and a new anchor point is formed between the spherical SiO₂ and surrounding resin. The first metal layer can grasp the spherical SiO₂ tightly like a “claw”, thereby improving the bonding force between the first metal layer and the surface of the dielectric material layer.

The material of the first metal layer is not limited in this application, and may be any metal material having electrical conductivity, for example, gold, silver, or copper.

Step S15. Perform an electroplating treatment on the first metal layer after the first metal layer is obtained, to form a second metal layer of a second thickness, where the second metal layer has the same pattern as a target wiring layer.

In a specific embodiment, a photoresist may be coated on the first metal layer. A pattern of the photoresist covering the first metal layer is opposite to the pattern of the target wiring layer. Next, the second metal layer is electroplated on the first metal layer coated with the photoresist. Part of the second metal layer covers a region of the first metal layer that is not covered by the photoresist, and other part covers a region provided with the photoresist. Finally, the photoresist is removed, the part of the second metal layer covering the photoresist is removed, and the part of the second metal layer covering the first metal layer is kept. In this way, the second metal layer with the same pattern as the target wiring layer is obtained on the first metal layer.

Step S16. Remove metal deposited on a first region of the first metal layer, to form a wiring layer on the target surface, where the first region is a region that is not covered by the second metal layer.

Because the bonding force between the first metal layer and the surface of the dielectric material layer is strong, the bonding force between the wiring layer electroplated on the first metal layer and the surface of the dielectric material layer is also strong.

In an embodiment, the metal deposited in the region of the first metal layer that is not covered by the second metal layer may be removed through a displacement reaction. For example, the material of the first metal layer is copper, and the metal deposited in the region of the first metal layer that is not covered by the second metal layer may be replaced by using a ferric chloride solution.

It should be noted that, the material of the second metal layer is not limited in this application, and may be any metal material having electrical conductivity, for example, gold, silver, or copper.

It should be further noted that, the thickness of the first metal layer is less than the thickness of the second metal layer. Generally, the thickness of the first metal layer ranges from 0.5 μm to 1 μm, and the thickness of the second metal layer is usually about 20 μm. Therefore, in the step of removing the metal deposited in the region of the first metal layer that is not covered by the second metal layer, even if there is partial damage to the second metal layer, the damage is essentially negligible.

Further, to ensure the economic cost in process implementation to the greatest extent, the existing process procedure can be fully utilized, and a new process can be avoided as much as possible. Based on this, a material that can be eroded by the treatment reagents used in a process of an existing Desmear process treatment may be used for the sacrificial layer in this application.

The above content describes the treatment reagents used in the process of the Desmear process treatment, including an alkaline potassium permanganate solution and sulfuric acid. Based on this, a material that can be eroded by the alkaline potassium permanganate solution or the sulfuric acid may be used for the sacrificial layer in this application.

In an embodiment, a material whose volume can be reduced after being eroded by the sulfuric acid the sacrificial layer may be used for the sacrificial layer. For the material whose volume can be reduced after being eroded by the sulfuric acid, reference may be made to the descriptions of the sacrificial layer in the above embodiments of the dielectric material. Details are not described herein again. For ease of description, a surface treatment method for a dielectric material using Na₂CO₃ to form the sacrificial layer is used as an example for description below.

As shown in FIG. 3C, in a surface treatment method for a dielectric material using Na₂CO₃ to form the sacrificial layer, a Desmear process system may be directly used, and includes a swelling and bulking stage, an oxidative degumming stage, and a neutralization stage.

For the swelling and bulking stage and the oxidative degumming stage, reference may be made to the descriptions of step S11 and step S12. Details are not described herein again.

In the neutralization stage, in an aspect, the sulfuric acid in a process of a conventional Desmear process treatment is used to neutralize the alkaline potassium permanganate solution in the oxidative degumming stage, and in another aspect, the sulfuric acid can react with the sacrificial layer to produce a substance soluble in water and a gas (the reaction formula of sulfuric acid and Na₂CO₃ is: Na₂CO₃+H₂SO₄→Na₂SO₄+H₂O+CO₂). In this way, after the sacrificial layer covering the outer surface of the spherical SiO₂ is eroded by the sulfuric acid, a cavity is formed around the spherical SiO₂, or part of the spherical SiO₂ is disengaged.

In summary, if a material whose volume can be reduced after being eroded by the sulfuric acid is used for the sacrificial layer, during a surface treatment, the treatment reagent sulfuric acid used in the neutralization stage of the Desmear process system may be directly used without additional process procedures and other treatment reagents.

In another embodiment, a material whose volume can be reduced after being eroded by the alkaline potassium permanganate solution may be used for the sacrificial layer. For the material whose volume can be reduced after being eroded by the alkaline potassium permanganate solution, reference may be made to the embodiments describing the dielectric material. Details are not described herein again. For ease of description, the surface treatment method for a dielectric material using modified epoxy resin to form the sacrificial layer is described below as an example.

As shown in FIG. 3D, in the surface treatment method for a dielectric material using modified epoxy resin to form the sacrificial layer, the Desmear process may be directly used, and includes a swelling and bulking stage, the oxidative degumming stage, and the neutralization stage.

For the swelling and bulking stage, reference may be made to the descriptions of step S11. Details are not described herein again.

In this embodiment, the oxidative degumming stage may include a front oxidative degumming stage and a rear oxidative degumming stage. For the front oxidative degumming stage, reference may be made to the description of step S12. Details are not described herein again. In the rear oxidative degumming stage, the treatment reagent alkaline potassium permanganate solution used in the front oxidative degumming stage is still used. The modified epoxy resin in the sacrificial layer is more easily oxidized by the alkaline potassium permanganate solution than epoxy resin. Therefore, in the rear oxidative degumming stage, the sacrificial layer of the exposed spherical SiO₂ covered with the sacrificial layer can be oxidized and removed by the alkaline potassium permanganate solution, so that a cavity is formed around the spherical SiO₂, or part of the spherical SiO₂ is disengaged. After the rear oxidative degumming stage is completed, the process may enter the neutralization stage, and the same manner in the neutralization stage in the Desmear process may be maintained in the neutralization stage.

The modified epoxy resin is epoxy resin in which at least one ether bond and/or one hydroxyl is added to a skeleton and/or a side chain. For details, reference may be made to the foregoing embodiments describing the dielectric material, and details are not described herein again.

It should be noted that, in the surface treatment method for a dielectric material layer using the modified epoxy resin to form the sacrificial layer, the specific embodiment of the oxidative degumming stage is not limited in this application. For example, the surface of the dielectric material layer may be treated once by using the alkaline potassium permanganate solution, until the sacrificial layer of the exposed spherical SiO₂ covered with the sacrificial layer is oxidized and removed. In another example, the surface of the dielectric material layer may be treated repeatedly by using the alkaline potassium permanganate solution, until the sacrificial layer of the exposed spherical SiO₂ covered with the sacrificial layer is oxidized and removed.

In summary, if a material whose volume is reduced after being eroded by the alkaline potassium permanganate is used for the sacrificial layer, during a surface treatment, the treatment reagent alkaline potassium permanganate solution used in the oxidative degumming stage of the Desmear process system may be directly used without additional process steps and other treatment reagents.

It should be noted that, in the step of eroding the sacrificial layer on an outer surface of the spherical SiO₂ exposed from the target surface of the dielectric material layer by using a first solution (for example, the sulfuric acid or the alkaline potassium permanganate solution), the first solution may react with the sacrificial layer on the outer surface of the spherical SiO₂ exposed from the target surface of the dielectric material completely or incompletely, as long as the volume of the sacrificial layer is reduced, which is not limited in this application.

It should be further noted that, if the sacrificial layer is a multi-layer structure formed by stacking, in the step of eroding the sacrificial layer in the above surface treatment method, only an outermost structure of the sacrificial layer may be eroded, or a plurality of layers of structure may be eroded from outside to inside with the sacrificial layer as the outermost layer, which is not limited in this application. Corresponding treatment reagents are selected according to the materials of corresponding layers during the erosion of different layers of structure. For example, the sacrificial layer is a Na₂CO₃ covering layer and a modified epoxy resin covering layer from outside to inside. During the surface treatment, the Na₂CO₃ covering layer may be first eroded by using the sulfuric acid, and the modified epoxy resin covering layer may be eroded by using the alkaline potassium permanganate solution. Alternatively, the Na₂CO₃ covering layer may be eroded by using only the sulfuric acid.

This application further provides a package substrate, including one or more dielectric material layers, and/or, a core board. A wiring layer is bonded to a target surface of at least one dielectric material layer. At least one dielectric layer of the above package substrate is formed of the dielectric material provided in the above embodiments of this application. In this way, the development requirements in directions of a low CTE, a low dielectric constant, and a low loss of a dielectric in the package substrate can be satisfied, and the bonding force between the wiring layer and the surface of the dielectric layer is improved.

For example, the package substrate includes one dielectric material layer. In another example, the package substrate includes one dielectric material layer and one core board. In another example, the package substrate includes a plurality of dielectric material layers, and a core board is arranged between two adjacent dielectric material layers. In an aspect, the core board can support the dielectric material layers. In another aspect, glass fiber in the core board has a low CTE, satisfying the developing requirement of a low CTE of the package substrate.

It should be noted that, in the package substrate provided in this application, a wiring layer may be bonded to one surface or each of two surfaces of any dielectric layer, which is not limited in this application. For example, the package substrate includes two dielectric layers. A wiring layer is bonded to each of an upper surface and a lower surface. In another example, the package substrate includes two dielectric layers. A wiring layer is bonded to each of an upper surface and a lower surface of one of the dielectric layers, and a wiring layer is bonded to an upper surface of an other dielectric layer.

This application further provides an electronic device, including the package substrate provided in this application, a component layer, and a main board. The package substrate is arranged between the component layer and the main board. The component layer includes a passive element 60 and/or a chip 50.

As shown in FIG. 4A, the package substrate may include two dielectric material layers, a first dielectric material layer 10, a second dielectric material layer 20, a core board 30 arranged between the first dielectric material layer 10 and the second dielectric material layer 20, and a wiring layer 40 bonded to each of target surfaces of the first dielectric material layer 10 and the second dielectric material layer 20. The dielectric material layer provided in the above embodiments of this application is used for both the first dielectric material layer 10 and the second dielectric material layer 20. That is, at least part of the outer surface of the spherical SiO₂ filled in the resin is covered with the sacrificial layer of the dielectric material. Compared with a conventional core board, an advantage of using the dielectric material layer provided in the embodiments of this application lies in that the dielectric material layer provided in the embodiments of this application has no interwoven glass fiber. In this way, it is easy to form a blind via of a small size by laser drilling in the dielectric material layer, and then fine wiring is performed through a Desmear process and a SAP process, thereby implementing high-density interconnection of the chip 50 and the passive element 60 (for example, a resistor element, an inductor element, and a capacitor element).

In a specific embodiment, as shown in FIG. 4A, a first blind via 110 is provided in the first dielectric material layer 10, a second blind via 310 is provided in the core board 30, and a third blind via 210 is provided in the second dielectric material layer 20. A wiring layer 40 is prepared on each of a first surface 120 and a second surface 130 opposite to each other of the first dielectric material layer 10, and a wiring layer 40 is also prepared on each of a third surface 220 and a fourth surface 230 opposite to each other of the second dielectric material layer 20. In this way, the passive element 60 located above the first dielectric material layer 10 and/or a first part of pins in the chip 50 may be connected to the wiring layer 40 on the first surface 120, the passive element 60 and/or a second part of pins in the chip 50 may be connected to the wiring layer 40 on the second surface 130 through the first blind via 110. The passive element 60 and/or a third part of pins in the chip 50 may be connected to the wiring layer 40 on the third surface 220 through the first blind via 110 and the second blind via 120. The passive element 60 and/or a fourth part of pins in the chip 50 may be connected to the wiring layer 40 on the fourth surface 230 through the first blind via 110, the second blind via 310, and the third blind via 210. The wiring layer 40 on the fourth surface 230 is connected to a main board 70. Fine wiring is performed on the package substrate provided in this application in the above, thereby implementing the high-density interconnection of the chip 50 and the passive element 60.

It should be noted that, a connection manner between the passive element 60 and/or the first part of pins in the chip 50 and the wiring layer 40 on the first surface 120 and a connection manner between the wiring layer 40 on the fourth surface 230 and the main board 70 are not limited in this application. In an embodiment, the passive element 60 and/or the first part of pins in the chip 50 may be connected to the wiring layer 40 on the first surface 120 by a first solder ball 80, and the wiring layer 40 on the fourth surface 230 may be connected to the main board 70 by a second solder ball 90.

It should be further noted that, the wiring layer 40 includes a plurality of conductive lines. The conductive lines corresponding to the wiring layers 40 on the first surface 120, the second surface 130, the third surface 220, and the fourth surface 230 may be the same or different, which may be set according to an actual requirement and is not limited in this application.

It should be further noted that, a conductive layer is provided in each of the first blind via 110, the second blind via 310, and the third blind via 210. In this way, the conductive lines respectively corresponding to the first blind via 120 on the first surface 120 and the second surface 130 may be connected by the conductive layer in the first blind via 110. The conductive lines respectively corresponding to the second blind via 310 on the second surface 130 and the third surface 220 may be in conduction by the conductive layer in the second blind via 310. The conductive lines respectively corresponding to the third blind via 210 on the third surface 220 and the fourth surface 230 may be connected by the conductive layer in the third blind via 210.

It should be further noted that, the structure that the package substrate in which the chip and the passive element are packaged shown in FIG. 4A is only for exemplary description, and represents no limitation on the structure of the electronic device provided in this application. For example, the electronic device provided in this application may include more or fewer dielectric material layers. In another example, the electronic device provided in this application may include more or fewer chips and passive elements.

For same or similar parts in the embodiments in this specification, reference may be made to these embodiments, especially the parts in the embodiments corresponding to the surface treatment method, the package substrate, and the electronic device may refer to the parts in embodiments of the dielectric material layer.

This application is described in detail above with reference to specific embodiments and exemplary examples, but these descriptions should not be construed as a limitation on this application. A person skilled in the art should understand that, without departing from the spirit and scope of this application, various equivalent replacements, modifications, or improvements can be made to the technical solutions of this application and the embodiments thereof, which all fall within the scope of this application. The protection scope of this application shall be subject to the appended claims.

1.-17. (canceled)

18. A surface treatment method for a dielectric material layer, wherein the method comprises:
performing a swelling and bulking treatment on a target surface of the dielectric material layer, wherein the target surface is a surface to be bonded to a wiring layer;
performing an oxidation treatment on the target surface of the dielectric material layer, wherein the oxidation treatment removes resin and exposes spherical SiO₂ covered with a sacrificial layer; and
eroding the sacrificial layer on an outer surface of the spherical SiO₂ exposed from the target surface using a first solution, wherein eroding the sacrificial layer forms a cavity around the spherical SiO₂ or disengages part of the spherical SiO₂ from the dielectric material.

19. The method according to claim 18, further comprising:
depositing a first metal layer of a first thickness on the target surface;
performing an electroplating treatment on the first metal layer, to form a second metal layer of a second thickness, wherein the second metal layer has a same pattern as a target wiring layer, and the second thickness is greater than the first thickness; and
removing metal deposited on a first region of the first metal layer, to form the target wiring layer on the target surface, wherein the first region is not covered by the second metal layer in the first metal layer.

20. A package substrate, comprising:
a first dielectric material layer comprising resin and spherical SiO₂ in the resin; and
a wiring layer on a first surface of the first dielectric material layer;
wherein an outer surface of at least part of the spherical SiO₂ is covered with a sacrificial layer; and
wherein the sacrificial layer is capable of being eroded by a first solution that does not react with the spherical SiO₂, and the first solution has a stronger capability of eroding the sacrificial layer than a capability of eroding the resin.

21. The package substrate according to claim 20, wherein the sacrificial layer is inorganic matter capable of being eroded by an acid solution, and products produced by the sacrificial layer reacting with the acid solution comprise at least one of a salt soluble in water, a gas, or water.

22. The package substrate according to claim 21, wherein the sacrificial layer comprises at least one material of Na₂CO₃, K₂CO₃, NaHCO₃, or KHCO₃.

23. The package substrate according to claim 20, wherein the sacrificial layer adopts organic matter capable of being hydrolyzed in an acid solution.

24. The package substrate according to claim 23, wherein the organic matter is protein, lipid, or polysaccharide.

25. The package substrate according to claim 20, wherein the sacrificial layer is formed of organic matter modified epoxy resin or modified cyanate capable of being eroded by an alkaline oxidant, wherein the modified epoxy resin is epoxy resin in which at least one ether bond or one hydroxyl is added to a skeleton or a side chain; and the modified cyanate is cyanate in which at least one ether bond or one hydroxyl is added to a skeleton or a side chain.

26. The package substrate according to claim 25, wherein the alkaline oxidant is an alkaline potassium permanganate solution.

27. The package substrate according to claim 20, wherein a thickness of the sacrificial layer ranges from 0.5 μm to 1 μm.

28. The package substrate according to claim 20, wherein a mass percent of the spherical SiO₂ in the resin in the first dielectric material layer accounts is greater than or equal to 60%, spherical SiO₂ of different particle diameters is in the resin, and the particle diameters of the spherical SiO₂ range from 1 μm to 5 μm.

29. The package substrate according to claim 20, further comprising:
a second dielectric material layer and a core board, wherein the core board is between the first dielectric material layer and the second dielectric material layer; and
wherein the second dielectric material layer comprises resin and spherical SiO₂ in the resin, and an outer surface of at least part of the spherical SiO₂ of the second dielectric material layer is covered with the sacrificial layer in the second dielectric material layer.

30. An electronic device, comprising:
a package substrate, a component layer, and a main board, the package substrate being between the component layer and the main board, and the component layer comprising a passive element or a chip;
wherein the package substrate comprises a first dielectric material layer, and the first dielectric material layer comprises resin and spherical SiO₂ in the resin, and an outer surface of at least part of the spherical SiO₂ is covered with a sacrificial layer; and
wherein the sacrificial layer is capable of being eroded by a first solution that does not react with the spherical SiO₂, and the first solution has a stronger capability of eroding the sacrificial layer than a capability of eroding the resin.

31. The electronic device according to claim 30, wherein the sacrificial layer is formed of inorganic matter capable of being eroded by an acid solution, or the sacrificial layer adopts organic matter capable of being hydrolyzed in an acid solution; and
wherein products produced by the sacrificial layer reacting with the acid solution comprise at least one of a salt soluble in water, a gas, or water.

32. The electronic device according to claim 30, wherein the sacrificial layer is formed of organic matter modified epoxy resin or modified cyanate capable of being eroded by an alkaline oxidant, wherein the modified epoxy resin is epoxy resin in which at least one ether bond or one hydroxyl is added to a skeleton or a side chain; and the modified cyanate is cyanate in which at least one ether bond or one hydroxyl is added to a skeleton or a side chain.

33. The electronic device according to claim 30, wherein a thickness of the sacrificial layer ranges from 0.5 μm to 1 μm.

34. The electronic device according to claim 30, wherein a mass percent of the spherical SiO₂ in the resin in the dielectric material layer accounts is greater than or equal to 60%, the spherical SiO₂ of different particle diameters is in the resin, and the particle diameters of the spherical SiO₂ range from 1 μm to 5 μm.

35. The electronic device according to claim 30, wherein:
a first blind via is in the first dielectric material layer;
a wiring layer is prepared on each of a first surface and a second surface opposite to each other of the first dielectric material layer; and
the passive element or a first part of pins in the chip are connected to the wiring layer on the first surface, and the passive element or a second part of pins in the chip are connected to the wiring layer of the second surface through the first blind via.

36. The electronic device according to claim 30, wherein the package substrate further comprises a second dielectric material layer and a core board, wherein the core board is between the first dielectric material layer and the second dielectric material layer; and
wherein, the second dielectric material layer comprises resin and spherical SiO₂ in the resin, and an outer surface of at least part of the spherical SiO₂ is covered with the sacrificial layer.

37. The electronic device according to claim 32, wherein
a second blind via is in a core board, and a third blind via is provided in a second dielectric material layer;
a wiring layer is prepared on each of a third surface and a fourth surface opposite to each other of the second dielectric material layer;
the passive element or a third part of pins in the chip are connected to the wiring layer on the third surface through the first blind via and the second blind via, and the passive element or a fourth part of pins in the chip are connected to the wiring layer on the fourth surface through the first blind via, the second blind via, and the third blind via; and
the wiring layer on the fourth surface is connected to the main board.
